(19) United States
(12) Patent Application Publication
(10) Pub. No.: US 2012/0061549 A1
(43) Pub. Date: Mar. 15, 2012

(54) Hands-Free Support for Mobile Electronic Devices

(76) Inventor: Scott Quillian Rogers, St. Petersburg, FL (US)

(21) Appl. No.: 13/232,897

(22) Filed: Sep. 14, 2011

Related U.S. Application Data
(60) Provisional application No. 61/383,176, filed on Sep. 15, 2010.

(51) Int. Cl. H05K 7/00; F16M 11/20; F16M 13/00

(52) U.S. Cl. 248/440.1; 248/346.01; 248/346.5; 248/346.03

(57) ABSTRACT

An apparatus used to provide hands-free support for mobile electronic devices, which utilizes a platform, adjustable straps, and a harness, to allow the user to optimize the viewing angle of the supported mobile electronic device without the discomfort and inconvenience of holding the mobile electronic device in their hand. In addition, support bars and stabilizers on the ends of the support bars can be implemented to further improve comfort to the user and stability of the hands-free support during use.

### CROSS-REFERENCE TO RELATED APPLICATIONS

This application is related to provisional patent application Ser. No. 61/383,176 filed Sep. 15, 2010, and claims the benefit of this earlier filing date.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC

Not Applicable

### BACKGROUND OF THE INVENTION

1. Field of the Invention

This invention relates to mechanisms used for supporting mobile electronic devices. such as tablet computers, mp3 players, smart phones, and e-book readers that can be utilized for audio-visual media including, but not limited to, books and periodicals in a digital format, as well as movies, television programs, music. video games, and/or internet content, as well as other computing functions that can be performed on mobile electronic devices.

2. Background Art

The present invention provides an improved apparatus for supporting mobile electronic devices, such as tablet computers, smart phones, and e-book readers. More specifically, the present invention relates to an apparatus that enables the user to perceive the content on a mobile electronic device in a more convenient and comfortable manner since the user's hands will not have to be used to hold the mobile electronic device. This is of particular concern as the battery-life, bandwidth, and functionality of mobile electronic devices has increased and users view content such as movies and books on mobile electronic devices for prolonged periods of time with greater frequency. Holding a mobile electronic device for such a prolonged period of time can. cause discomfort in one's hands and arms, while also further limiting the user's ability to perform other tasks requiring use of the hands while viewing the mobile electronic device. Further, the present invention provides an adjustable support for use with mobile electronic devices of varying sizes. In addition, the present invention provides a support that is lighter in weight and less cumbersome than other mechanisms designed for supporting other wireless devices such as laptop computers. The present invention also enables users to utilize the support in various positions including, but not limited to, walking, standing, and sitting, as well as allowing for adjustment of the platform where the mobile electronic device rests to provide a variety of viewing angles for the user.

U.S. Pat. No. 4,715,293 to Cobbs (1987) discloses an apparatus where the user's body supports a hand-operated instrument such as a laptop computer. In Cobbs, the platform where the instrument rests functions like a stationary desk, which is incapable of turning to improve the user's viewing angle. More specifically, the apparatus in Cobbs is supported primarily by the user's shoulders, which inherently only permits the instrument to be located right in front and straight down in front of the user, providing only a single viewing angle. Further, a primary function of the apparatus in Cobbs is to at all times have the computer device in proximity to the user's hands to allow proper use of the device's keyboard, while optimizing the user's ability to view the device is not taken into consideration.

U.S. Patent Application No. US 2003/0060239 A1 by Epstein (2003) discloses an apparatus that is used to read incoming messages on portable devices at varying angles; however, it does not specifically provide a means for the user to view other content such as movies, books, and information from the internet. Further, the apparatus in Epstein requires users to hold the portable device in their hand; therefore, it does not address the problem of discomfort in holding a mobile electronic device for a prolonged period of time or providing the user with the ability to perform other tasks requiring the use of their hands while viewing content on the mobile electronic device.

### BRIEF SUMMARY OF THE INVENTION

The present invention includes a hands-free support for mobile electronic devices. The hands-free support provides an adjustable flat platform on which mobile electronic devices of various shapes and sizes can rest. The hands-free support further includes one or more removable support bars attached to the lip at the bottom edge of the platform, which provide stability, as well as the ability to adjust the viewing angle of the mobile electronic device resting on the platform. The platform and support bar(s) are constructed of a durable non-corrosive material. In addition, the hands-free support includes two adjustable straps, which attach in two distinct places on both the left and right sides of the platform. The other ends of the adjustable straps are attached to a harness. Users of the hands-free support wear the harness around their neck. Further, the adjustable straps, support bar(s), and the platform itself can each be easily adjusted to allow the user to optimize viewing of the mobile electronic device in a variety of positions using the hands-free support.

### BRIEF DESCRIPTION OF THE DRAWING

FIG. 1 is a perspective view of the hands-free support in the preferred embodiment, which includes a mobile electronic device shown for illustrative purposes only.

### DETAILED DESCRIPTION OF THE INVENTION

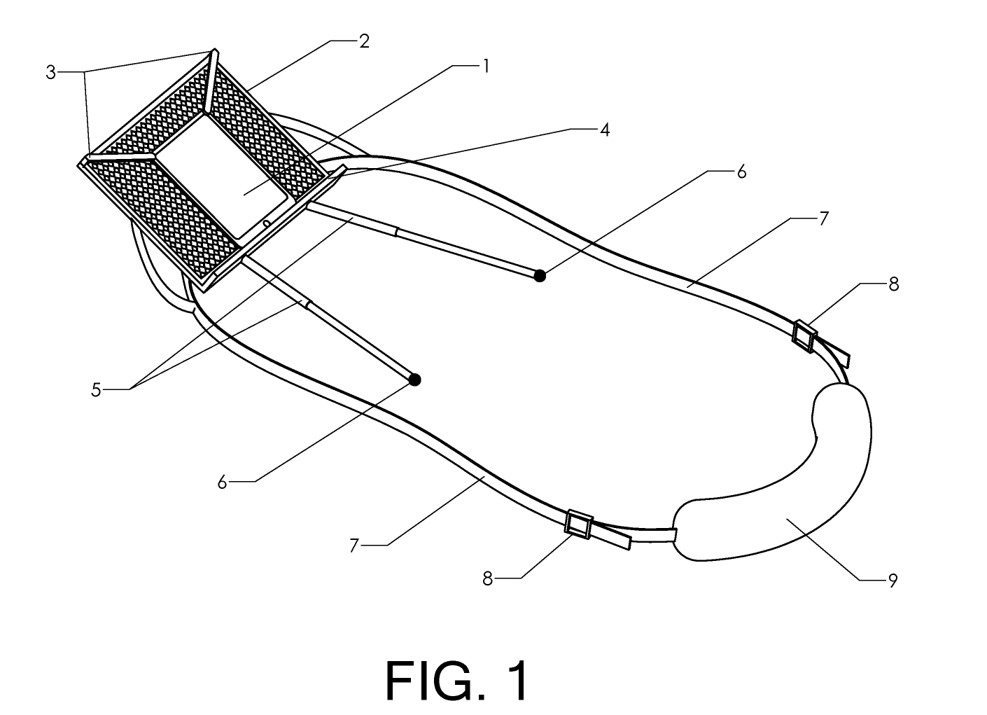

Referring now to the drawing, wherein like reference characters designate like or corresponding parts, there is shown in FIG. 1 the preferred embodiment of the hands-free support. Unless otherwise noted, the components of the hands-free support are to be constructed of a durable, light-weight, and non-corrosive material such as metal or plastic.

The platform 2 includes a flat top surface and is of sufficient thickness to provide stability and support the weight of common mobile electronic devices. In the preferred embodiment, the platform 2 is rectangular with four sides forming four right angles. When in use, a mobile electronic device 1, as shown in FIG. 1 for illustrative purposes only, is placed on the platform 2, with the screen or viewing area of the mobile electronic device 1 facing up. In the preferred embodiment, the top surface of the platform 2 incorporates a non-slip surface to provide greater support and protection for the mobile electronic device 1. In the upright position, as shown in FIG. 1, the platform 2 includes a top edge, bottom edge, and right and left edges, and these edges shall be referred to as such herein. The platform 2 is further capable of being expanded to accommodate mobile electronic devices of varying sizes by attaching additional platforms to the platform 2 or through adjustable sliding extensions which allow the platform 2 to expand both vertically and horizontally. The length, width, and thickness of the platform 2 can vary depending on the size and weight of the mobile electronic device 1 being viewed. Accordingly, the dimensions, as well as the relative positions, for the other components of the hands-free support may be reasonably modified from what is shown in the preferred embodiment in order to adapt to the dimensions of the platform 2 as dictated by the size and weight of the mobile electronic device 1.

In order to provide further support and protection for the mobile electronic device 1, in the preferred embodiment, fasteners 3 are attached to the platform 2. Additionally, the fasteners 3 are attached to the mobile electronic device 1. The fasteners 3 may be in a variety of formats including, but not limited to, a hook and loop, straps, or Velcro, provided the fasteners 3 are capable of being attached to both the platform 2 and the mobile electronic device 1.

At the bottom edge of the platform 2 is a lip 4 that protrudes outward from the top surface of the platform 2. In the preferred embodiment, the lip 4 protrudes approximately 1.0 inch outward from the top surface of the platform 2, as this is a sufficient distance to accommodate typical mobile electronic devices without adding excessive weight to the hands-free support or having a detrimental effect on the stability of the hands-free support. Additionally, in the preferred embodiment, the lip 4 extends along the entire length of the bottom edge of the platform 2 in order to provide greater flexibility in optimizing the viewing angle of the mobile electronic device 1.

In addition, one or more support bars 5 are attached at one end, as by ball joints or the like, to the bottom of the lip 4. These connections by ball joints, or pivots, allows for the support bars 5 to be rotated to a wide range of positions relative to the platform 2. In the preferred embodiment, the support bars 5 are telescopic and are capable of being extended to approximately 3.0 feet. Alternatively, the support bars 5 may be of a fixed length.

As shown in FIG. 1, in the preferred embodiment, two support bars 5 are included in the hands-free support. One of the support bars 5 is attached to the lip 4 at a point approximately midway between the left edge of the platform 2 and the midpoint of the bottom edge of the platform 2, while the other support bar 5 is attached to the lip 4 at a point approximately midway between the right edge of the platform 2 and the midpoint of the bottom edge of the platform 2. During use, the support bar(s) 5 may be extended to a desired length and locked in place while being used to support the platform 2 by positioning them to either side of the user or on the user's body. In addition, stability and support for the platform 2 may be increased by placing the unconnected ends of the support bar(s) 5 against the back of a seat when the hands-free support is being utilized while the user is seated. The location of the support bar(s) 5 on the lip 4 and the connection by ball joints of the support bar(s) 5 to the lip 4, as well as the flexibility to retract and extend the support bar(s) 5 as provided for in the preferred embodiment, each contribute to the hands-free support allowing the user to optimize viewing of the mobile electronic device 1 while it is resting on the platform 2. Additionally, in the preferred embodiment, the support bar(s) 5 can be detached from the lip 4 in order for the user of the hands-free support to achieve the desired comfort, stability, and viewing angle of the mobile electronic device 1, depending upon the circumstances in which the hands-free support is being used.

Alternatively, the support bars 5 may be connected with a strap or the like to form a brace, which can be rested against the user's body to provide additional support and stability while using the hands-free support. Further, the support bar(s) 5, may alternatively include a contoured brace made of a durable, non-corrosive material, attached to the unconnected end(s) of the support bar(s) 5, wherein the contoured brace can be rested against the user's body to provide additional support and stability while using the hands-free support.

Further, in the preferred embodiment, a stabilizer 6 made of a durable material such as rubber or cushioned material is placed on the unconnected ends of each support bar 5. The stabilizer 6 may vary in size dependent upon the user's preference, provided it covers the unconnected end of the support bar 5. The stabilizer 6 increases comfort to the user and stability for the hands-free support when in use. Further, the stabilizer 6 helps to prevent damage to furniture when the user of the hands-free support is seated.

Two adjustable straps 7 are connected to the platform 2 with one of the adjustable straps 7 connected to the left side of the platform 2 and the other adjustable strap 7 attached to the right side of the platform 2. In the preferred embodiment, the adjustable straps 7 are each attached at two distinct, but corresponding points on the respective sides of the platform 2 with one connection made above the midpoint of the side of the platform 2 and the other connection made below the midpoint of the side of the platform 2. The adjustable straps 7 are made of a durable. flexible material such as canvas. In addition, a clasp 8 is located on each of the adjustable straps 7, which allows the length of the adjustable straps 7 to be adjusted in order to optimize viewing of the mobile electronic device I by the user of the hands-free support. In addition, the clasps 8 are used to secure the adjustable straps 7 at the desired length.

A harness 9 made of a durable material is formed into a flattened-out “U” shape. Each end of the harness 9 is connected to one of the ends of the adjustable straps 7 that is not connected to the platform 2. In the preferred embodiment, the harness 9 is made of a soft, padded or cushioned material to maximize comfort for the user of the hands-free support during extended use. When work around the user's neck and further combined with the adjustable straps 7 and clasps 8, the harness 9 provides additional support and stability for the platform 2 while viewing a mobile electronic device 1 on the hands-free support.

Alternatively, the platform 2 may be equipped with legs on the back side of the platform 2, which would enable the hands-free support to be used as a stand for optimizing the view of a mobile electronic device 1 to be viewed while sitting on a table, desk, counter or the like.

It should be understood that the foregoing disclosure relates primarily to the preferred embodiment of the invention and that numerous modifications or alterations may be made therein without departing from the spirit and scope of the invention as set forth in the appended claims.

The invention claimed is:

1. An apparatus for supporting a mobile electronic device, which comprises:
(a) a platform made of a durable, non-corrosive material having a lip at its bottom edge;
(b) two adjustable straps made of a durable, flexible material, where one strap is connected to the left side of the platform and the other strap is connected to the right side of the platform; and
(c) a harness to be worn around the neck of a human user, which is attached at its ends to the respective opposite ends of the adjustable straps connected to the platform.

2. An apparatus as recited in claim 1, further comprising one or more support bars connected to the lip at the bottom edge of the platform.

3. An apparatus as recited in claim 2, wherein the support bars are removable.

4. An apparatus as recited in claim 2, wherein the support bars are able to be retracted and extended.

5. An apparatus as recited in claim 2, wherein stabilizers are attached to the unconnected ends of the support bars.

6. An apparatus as recited in claim 1, further comprising fasteners attached to the platform, which can be further attached to a mobile electronic device.

7. An apparatus as recited in claim 1, further comprising legs attached to the back of the platform to allow the platform to function as a stand supported by a flat surface rather than a human user.
